(19) United States
(12) Patent Application Publication
(10) Pub. No.: US 2026/0146316 A1
(43) Pub. Date: May 28, 2026

(54) WEB COATING METHOD AND VENTED COOLING DRUM WITH INTEGRAL ELECTROSTATIC CLAMPING

(71) Applicant: Elevated Materials Germany GmbH, Alzenau (DE)

(72) Inventors: Vijay D. Parkhe, San Jose, CA (US); Visweswaren Sivaramakrishnan, Cupertino, CA (US); David Masayuki Ishikawa, Mountain View, CA (US); Thomas Deppisch, Aschaffenburg (DE)

(21) Appl. No.: 19/122,181

(22) PCT Filed: Oct. 3, 2023
(86) PCT No.: PCT/US2023/034353

§ 371 Date: Apr. 17, 2025

Related U.S. Application Data
(60) Provisional application No. 63/412,696, filed on Oct. 3, 2022.

(51) Int. Cl. C23C 14/56; C23C 14/50; H02N 13/00

(52) U.S. Cl. CPC C23C 14/56; C23C 14/505; H02N 13/00

(57) ABSTRACT

A rotatable drum is provided for supporting a substrate. The rotatable drum includes a curved drum surface for supporting the substrate. The curved drum surface includes a dielectric portion and an electrode coupled to a power source. The electrode is electrically coupled to the curved drum surface and capable of chucking and dechucking the substrate from the curved drum surface at one or more circumferential segments of the curved drum surface.

### BACKGROUND

### Field

Embodiments described herein generally relate apparatus and methods for fabricating metal electrodes, more specifically lithium-containing anodes, high performance electrochemical devices, such as primary and secondary electrochemical devices, including the aforementioned lithium-containing electrodes.

### Description of the Related Art

Lithium (Li) ion batteries have played a vital role in the development of current generation mobile devices, microelectronics, and electric vehicles. A typical Li-ion battery is made of a positive electrode (cathode), a negative electrode (anode), an electrolyte to conduct ions, a porous separator membrane (electrical insulator) between the two electrodes to keep them physically apart, and the packaging.

Methods of depositing lithium on substrates, such as large flexible substrates can be temperature sensitive and cause the formation of wrinkles and other defects. The substrate may be guided on and supported by a rotatable coating drum with a curved drum surface. A vapor may be deposited on the substrate while the substrate moves on the curved drum surface of the rotatable drum past the evaporation source or sources. Drums may be used to maintain and control temperature of the substrates by cooling and pressurizing a backside of the substrate using high pressure to maintain a uniform gap height between the substrate and the curved drum surface. Low pressure can be used for wide thin film substrates due to particles, film stress, or misalignment causing machine-direction wrinkles.

Therefore, there is a need for apparatuses and methods to maintain low pressure and enhanced substrate cooling to improve throughput.

### SUMMARY

In one aspect, a rotatable drum for supporting a substrate is provided. The rotatable drum includes a curved drum surface for supporting the substrate and including a dielectric portion. The rotatable drum further includes an electrode coupled to a power source, the electrode electrically coupled to the curved drum surface and capable of chucking and de-chucking the substrate from the curved drum surface at one or more circumferential segments of the curved drum surface.

Embodiments may include one or more of the following. The dielectric portion includes a material selected from the group consisting of diamond-like carbon, aluminum oxide, boron nitride, polyimide, and combinations thereof. The electrode is a fixed electrode spaced radially inward from the curved drum surface and is electrically coupled to the curved drum surface by a plurality of movable electrode spokes. The electrode includes a first hemisphere that is electrically grounded and a second hemisphere that is coupled to the power source. Each of the one or more circumferential segments includes at least one cooling channel and one or more gas passages extending from an inner surface of the circumferential segment to the curved drum surface. The dielectric portion of the curved drum surface includes a first polyimide layer, a patterned electrode disposed over the first polyimide layer, and a second polyimide layer disposed over the patterned electrode. The patterned electrode includes copper. The patterned electrode includes a plurality of mesas. The mesas are polygon shaped. The mesas are arranged in rows extended from one edge of the rotatable drum to an opposite edge of the rotatable drum. The rotatable drum further includes surface channels disposed between adjacent rows of the patterned electrode. The rows alternate between a first row that is coupled to a power source and a second row that is coupled to a ground. The rotatable drum further includes a heat sink disposed radially inward from the curved drum surface and radially outward from the electrode. A vapor deposition apparatus, including the rotatable drum and an evaporation source configured to deposit a material onto a substrate disposed on the curved drum surface of the rotatable drum.

In another aspect, an electrode assembly for electrostatically chucking a substrate to a rotatable drum is provided. The electrode assembly includes a first protective layer interfacing the rotatable drum, an electrode disposed over the first protective layer, and a second protective layer disposed over the electrode and including a curved surface for supporting the substrate.

Embodiments may include one or more of the following. The first and second protective layers include aluminum oxide and the electrode includes aluminum or an alloy of aluminum. The electrode is arranged in a plurality of rows extending substantially parallel with respect to one another and extending from one edge of the rotatable drum to an opposite edge of the rotatable drum. The rows alternate between a first row that is coupled to power and a second row that is grounded and channels are disposed between the rows.

In yet another aspect, a method for coating a substrate in a vacuum chamber is provided. The method includes conveying a substrate over a curved surface of a rotatable drum, the substrate being electrostatically chucked to at least a portion of the curved surface of the rotatable drum. The method further includes evaporating a material in an evaporation crucible. The method further includes directing the evaporated material from the evaporation crucible to the substrate.

Embodiments may include one or more of the following. Conveying the substrate further includes retaining the substrate over the curved surface of the rotatable drum such that a gap is formed between the substrate and the curved surface of the rotatable drum. The method further includes providing a gas to the gap between a backside of the substrate and the curved surface of the rotatable drum. The substrate is conveyed in machine direction extending from an inlet side to an outlet side of the rotatable drum, and wherein the substrate is chucked at the inlet side and dechucked at the outlet side.

In another aspect, a non-transitory computer readable medium has stored thereon instructions, which, when executed by a processor, causes the process to perform operations of the above apparatus and/or method.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 illustrates a schematic cross-sectional view of one embodiment of an energy storage device incorporating an anode electrode structure, according to some embodiments described herein.

FIG. 2 illustrates a cross-sectional view of one embodiment of a dual-sided anode electrode structure, according to some embodiments described herein.

FIG. 3 illustrates a schematic sectional view of an evaporation source for depositing an evaporated material on a substrate, according to some embodiments described herein.

FIG. 4 illustrates a schematic sectional view of a vapor deposition apparatus, according to some embodiments described herein.

FIG. 5A illustrates a schematic view of the vapor deposition apparatus of FIG. 4 viewed along a rotation axis of a rotatable drum, according to some embodiments described herein.

FIG. 5B illustrates cross-sectional end view of a rotatable drum conveying a substrate, according to some embodiments described herein.

FIG. 6 illustrates a cross sectional view of a portion of a dielectric portion of the rotatable drum, according to some embodiments described herein.

FIG. 7 illustrates a top view of the dielectric portion of the rotatable drum, according to some embodiments described herein.

FIG. 8 illustrates a cross sectional end view of a dielectric portion coupled to a body of the drum, according to some embodiments described herein.

FIG. 9 illustrates an inside view of a drum, according to some embodiments described herein.

FIG. 10 illustrates a flow diagram illustrating a method for coating a substrate, according to some embodiments described herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure generally relate apparatus and methods for fabricating metal electrodes, more specifically lithium-containing anodes, high performance electrochemical devices, such as primary and secondary electrochemical devices, including the aforementioned lithium-containing electrodes.

Vapor deposition systems for coating a web substrate being guided on a rotatable coating drum are referred to herein as roll-to-roll (R2R) deposition systems. As described herein, flexible substrates can be considered to include among other things, films, foils, webs, strips of plastic material, metal, paper, or other materials. Typically, the terms “web,” “foil,” “strip,” “substrate” and the like are used synonymously.

Energy storage devices, for example, Li-ion batteries, typically include a positive electrode, for example, a cathode, and a negative electrode, for example, an anode, separated by a polymer separator with a liquid electrolyte. Solid-state batteries also typically include a positive electrode and a negative electrode but replace both the polymer separator and the liquid electrolyte with an ion-conducting material. Lithium is deposited onto substrates by evaporating molten lithium or lithium vapor onto a substrate, such as a graphite coated copper foils or copper foils. The substrates are maintained below a certain temperature as the lithium is being deposited on the front side of the substrates. Maintaining the temperature can include cooling a back side of a substrate, by venting gas between the drum surface that is supporting the substrate and the substrate. The deposition rate of the lithium on the substrate is limited by the rate of cooling on the backside of the substrate. The cooling gas is selected such that it does not react with lithium. In some embodiments, the cooling gas can be or include argon, helium, or a combination thereof.

In addition to providing the cooling gas to the back side of the substrate, a uniform gap distance between the substrate and the drum surface is generally maintained. Conventional solutions to retaining the substrate have included mechanical solutions, such as disposing retaining rollers about the drum to retain the substrate to the drum to prevent the substrate from ballooning off of the drum with the application of gas as the substrate is thermally expanding. These solutions can lead to edge damage and peeling. It has been discovered that the use of electrostatic clamping retains substrates to the drum and also maintains uniform gap between the substrate and the drum surface.

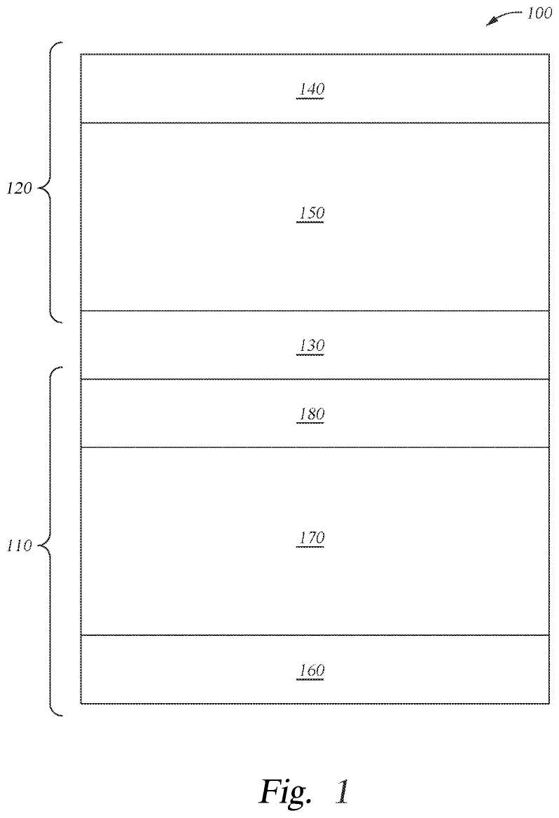

FIG. 1 illustrates a schematic cross-sectional view of one embodiment of an energy storage device 100 incorporating an anode electrode structure 110 formed according to embodiments described herein. The anode electrode structure 110 includes an anode film 170 having one or more protective film(s) 180 formed thereon. The energy storage device 100 may be a solid-state energy storage device or a lithium-ion based energy storage device. The energy storage device 100, even though shown as a planar structure, may also be formed into a cylinder by rolling the stack of layers; furthermore, other cell configurations, for example, prismatic cells, button cells, or stacked electrode cells, may be formed. The energy storage device 100 includes the anode electrode structure 110 and a cathode electrode structure 120, optionally with an electrolyte or polymer separator 130 positioned therebetween. The cathode electrode structure 120 includes a cathode current collector 140 and a cathode film 150.

In one or more embodiments, which can be combined with other embodiments, the one or more protective film(s) 180 include one or more ceramic materials. The ceramic material may be an oxide. In one embodiment, the one or more protective film(s) 180 include a material selected from, for example, aluminum oxide (Al₂O₃), aluminum oxynitride, aluminum nitride (AlN, aluminum deposited in a nitrogen environment), aluminum hydroxide oxide ((AlO(OH)) (e.g., diaspore ((α-AlO(OH))), boehmite (γ-AlO(OH)), or akdalaite (5Al₂O₃·H₂O)), calcium carbonate (CaCO₃), titanium dioxide (TiO₂), SiS₂, SiPO₄, silicon oxide (SiO₂), zirconium oxide (ZrO₂), hafnium oxide (HfO₂), MgO, TiO₂, Ta₂O₅, Nb₂O₅, LiAlO₂, BaTiO₃, boron nitride (BN), ion-conducting garnet, ion-conducting perovskite, ion-conducting anti-perovskites, porous glass ceramic, and the like, or combinations thereof. In particular embodiments, the one or more protective film(s) 180 are deposited using evaporation techniques as described herein.

In one or more embodiments, which can be combined with other embodiments, each layer of the one or more protective film(s) 180 is a coating or a discrete film having a thickness in a range of about 1 nanometer to about 3,000 nanometers (e.g., in the range of about 10 nanometers to about 600 nanometers; in the range of about 50 nanometers to about 100 nanometers; in the range of about 50 nanometers to about 200 nanometers; in the range of about 100 nanometers to about 150 nanometers).

The cathode electrode structure 120 includes the cathode current collector 140 with the cathode film 150 formed on the cathode current collector 140. It should be understood that the cathode electrode structure 120 may include other elements or films.

The current collectors 140, 160, on the cathode film 150 and the anode film 170, respectively, can be identical or different electronic conductors. In particular embodiments, at least one of the current collectors 140, 160 is a flexible substrate. The flexible substrate can be or include, one or more layers selected from plastic, polymer materials, metallized plastic, metals, paper, multilayers thereof, or a combination thereof. The flexible substrate may be or include a casting polypropylene (“CPP”) film, an oriented polypropylene (“OPP”) film, or a polyethylene terephthalate (“PET”) film. Alternatively, the flexible substrate may be a pre-coated paper, a polypropylene (PP) film, a polyethylene naphthalate (PEN) film, a polylactic acid (PLA) film, a polyimide (PI) film, a poly(methyl methacrylate) (PMMA) film, a cellulose tri-acetate (TAC) film, a polypropylene (PP) film, a polyethylene (PE) film, a polycarbonate (PC) film, or a PVC film. Examples of metals that the current collectors 140, 160 may be comprised of include aluminum (Al), copper (Cu), zinc (Zn), nickel (Ni), cobalt (Co), manganese (Mn), chromium (Cr), stainless steel, clad materials, alloys thereof, and a combination thereof. In one or more embodiments, which can be combined with other embodiments, at least one of the current collectors 140, 160 is perforated. In one or more embodiments, which can be combined with other embodiments, at least one of the current collectors 140, 160 includes a polymer substrate (e.g., polyethylene terephthalate (“PET”) coated with a metallic material. In one or more embodiments, which can be combined with other embodiments, the anode current collector 160 is a polymer substrate (e.g., a PET film) coated with copper. In another embodiment, the anode current collector 160 is a multi-metal layer on a polymer substrate. The multi-metal layer can be or include copper, chromium, nickel, alloys thereof, or any combination thereof. In one embodiment, the anode current collector 160 is a multi-layer structure that includes a copper-nickel cladding material. In one embodiment, the multi-layer structure includes a first layer of nickel or chromium, a second layer of copper formed on the first layer, and a third layer including nickel, chromium, or both formed on the second layer. In one or more embodiments, which can be combined with other embodiments, the anode current collector 160 is nickel coated copper. In one or more embodiments, which can be combined with other embodiments, the anode current collector 160 is graphite coated copper. Furthermore, current collectors may be of any form factor (e.g., metallic foil, sheet, or plate), shape and micro/macro structure.

In one or more embodiments, which can be combined with other embodiments, the cathode current collector 140 can be or include aluminum. The cathode current collector 140 can be or include aluminum deposited on a polymer substrate, for example, a PET film. The cathode current collector 140 may have a thickness below 50 μm, more specifically, 5 μm or, even more specifically 2 μm. The cathode current collector 140 may have a thickness from about 0.5 μm to about 20 μm, for example, from about 1 μm to about 10 μm; from about 2 μm to about 8 μm; or from about 5 μm to about 10 μm. The anode current collector 160 can be or include copper. The anode current collector 160 can be or include stainless steel. In one or more embodiments, which can be combined with other embodiments, the anode current collector 160 has a thickness of less than 50 μm, more specifically, less than or about 5 μm or, even more specifically less than or about 2 μm. In one or more embodiments, which can be combined with other embodiments, the anode current collector 160 has a thickness from about 0.5 μm to about 20 μm, for example, from about 1 μm to about 10 μm; from about 2 μm to about 8 μm; from about 6 μm to about 12 μm; or from about 5 μm to about 10 μm.

The cathode film 150 or cathode may be any material compatible with the anode and may include an intercalation compound, an insertion compound, or an electrochemically active polymer.

The anode electrode structure 110 includes the anode current collector 160 with the anode film 170 formed on the anode current collector 160. The anode electrode structure 110 can further include the one or more protective film(s) 180.

In one or more embodiments, which can be combined with other embodiments, the anode film 170 is constructed from lithium metal, lithium metal foil or a lithium alloy foil (e.g., lithium aluminum alloys), or a mixture of a lithium metal and/or lithium alloy and materials such as carbon (e.g., coke, graphite), nickel, copper, tin, indium, silicon, oxides thereof, or any combination thereof. The anode film 170 can be or include one or more intercalation compounds containing lithium or insertion compounds containing lithium. In particular embodiments, the anode film is a lithium metal film. In some embodiments, where the anode film 170 is or includes lithium metal, the lithium metal may be deposited using the methods described herein.

In one or more embodiments, which can be combined with other embodiments, the anode film 170 can be or include graphite, silicon, or any combination thereof. The anode film 170 can be or contain one or more carbonaceous materials, for example, natural graphite or artificial graphite, partially graphitized or amorphous carbon, petroleum, coke, needle coke, and various mesophases, silicon-containing graphite, silicon, nickel, copper, tin, indium, aluminum, silicon, oxides thereof, combinations thereof, or a mixture of a lithium metal and/or lithium alloy and materials such as carbon, for example, coke or graphite, nickel, copper, tin, indium, aluminum, silicon, oxides thereof, or combinations thereof. In one example, the anode film 170 can be or contain silicon-graphite. In another example, the anode film 170 can be or include graphite.

In one or more embodiments, which can be combined with other embodiments, where the anode film 170 is or includes graphite, silicon, or silicon-graphite, the anode film 170 has a layer of lithium formed on the surface of the anode film 170. The layer of lithium metal can have a thickness from about 20 μm to about 50 μm. The layer of lithium can be a pre-lithiation layer.

In one or more embodiments, which can be combined with other embodiments, the anode film 170 has a thickness from about 10 μm to about 200 μm, for example, from about 1 μm to about 100 μm; from about 10 μm to about 30 μm; from about 20 μm to about 30 μm; from about 1 μm to about 20 μm; or from about 50 μm to about 100 μm.

In one or more embodiments, which can be combined with other embodiments, the polymer separator 130 is a porous polymeric ion-conducting polymeric substrate. The porous polymeric substrate can be a multi-layer polymeric substrate. In particular embodiments, the porous polymeric substrate has a porosity in the range of about 20% to about 80% (e.g., in the range of about 28% to about 60%). The porous polymeric substrate may have an average pore size in the range of about 0.02 μm to about 5 μm (e.g., about 0.08 μm to about 2 μm). In particular embodiments, the porous polymeric substrate has a Gurley Number in the range of about 15 seconds to about 150 seconds. The porous polymeric substrate may be or include one or more polyolefin polymers. Examples of suitable polyolefin polymers include polypropylene, polyethylene, or combinations thereof. In one or more embodiments, which can be combined with other embodiments, the porous polymeric substrate is a polyolefin membrane. In one or more embodiments, which can be combined with other embodiments, the polyolefin membrane is a polyethylene membrane or a polypropylene membrane.

In one or more embodiments, which can be combined with other embodiments, the porous polymeric substrate has a thickness in a range from about 1 μm to about 50 μm, for example, in a range from about 3 μm to about 25 μm; in a range from about 7 μm to about 12 μm; or in a range from about 14 μm to about 18 μm.

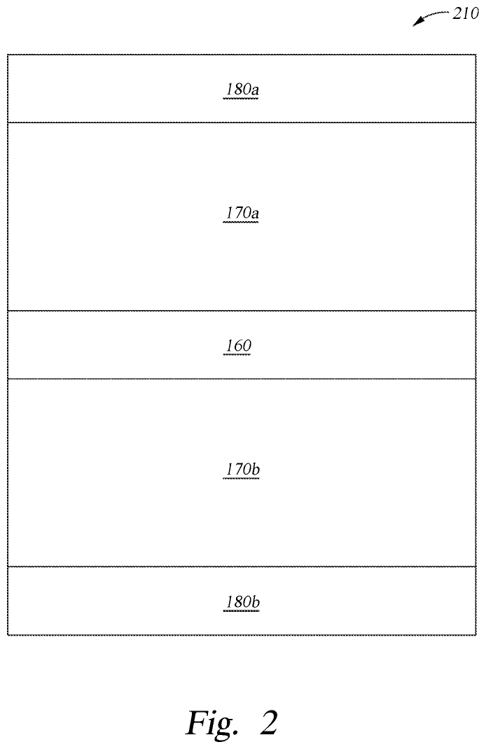

FIG. 2 illustrates a cross-sectional view of one embodiment of a dual-sided anode electrode structure 210 formed according to one or more embodiments described herein. The dual-sided anode electrode structure 210 includes the anode current collector 160 with the anode film 170a, 170b (collectively 170) formed on opposing sides of the anode current collector 160. The dual-sided anode electrode structure 210 further includes one or more protective film(s) 180a, 180b (collectively 180) formed on anode films 170a, 170b respectively.

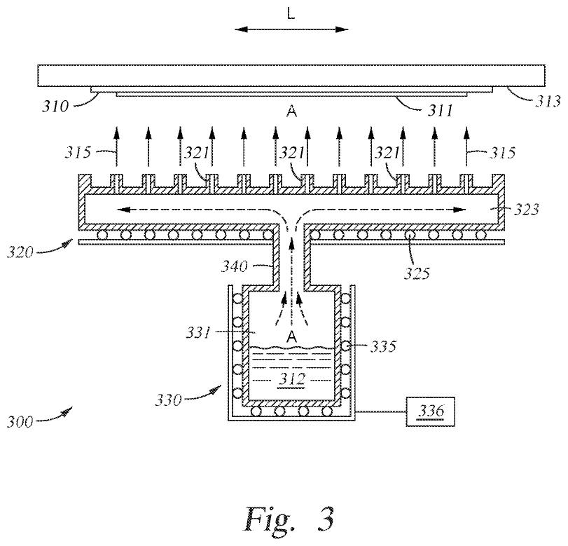

FIG. 3 is a schematic sectional view of an evaporation source 300 for depositing an evaporated material on a substrate 310 according to embodiments described herein. The substrate 310 may be supported by a substrate support 313, for example, for example, a surface of a drum. The evaporation source 300 includes an evaporation crucible 330 for heating a source material 312 to a temperature above the evaporation temperature or sublimation temperature of the source material 312, such that the source material 312 evaporates. The source material 312 can be a solid or liquid source material. The evaporation crucible 330 defines an inner volume 331 acting as a material reservoir for accommodating the source material 312 in a solid and/or liquid state, and a first heater 335 for heating the inner volume 331 of the evaporation crucible 330, such that the source material 312 evaporates. For example, the source material 312 may be a metal, for example, an alkali metal such as lithium or sodium, and the first heater 335 may be configured for heating the inner volume 331 of the evaporation crucible 330 to a temperature of about 600° C. or greater, particularly about 700° C. or greater, or about 800° C. or greater.

The evaporation source 300 further includes a vapor distributor 320 with a plurality of nozzles 321 for directing the material evaporated in the evaporation crucible 330 toward the substrate 310, such that a coating 311 is deposited on the substrate 310. The vapor distributor 320 may include an inner volume 323 that is in fluid communication with the inner volume 331 of the evaporation crucible 330, such that the evaporated material can stream from the inner volume 331 of the evaporation crucible 330 into the inner volume 323 of the vapor distributor 320 through a vapor conduit 340, for example, along a linear connection tube or passage. The plurality of nozzles 321 may be configured to direct the evaporated material from the inner volume 323 of the vapor distributor 320 toward the substrate 310.

In some embodiments, the vapor distributor 320 may be a vapor distribution showerhead having the plurality of nozzles 321 arranged in a 1-dimensional or 2-dimensional pattern for directing the evaporated material toward the substrate 310.

The evaporation crucible 330 is in fluid connection with the vapor distributor 320 via the vapor conduit 340 that extends from the evaporation crucible 330 to the vapor distributor 320 in a conduit length direction A. During evaporation, the vapor distributor 320 is typically provided at a second temperature that is higher than a first temperature inside the evaporation crucible 330 in order to prevent a material condensation on inner wall surfaces of the vapor distributor 320.

The evaporation source 300 may further include a first heater 335 for heating and evaporating the source material 312 in the inner volume 331 of the evaporation crucible 330 and a second heater 325 for heating the inner volume 323 of the vapor distributor 320. The first heater 335 and the second heater 325 can be individually controlled. For example, the first heater 335 may be configured to heat the evaporation crucible 330 to a first temperature and the second heater 325 may be configured to heat the vapor distributor 320 to a second temperature different from the first temperature, particularly above the first temperature. During vapor deposition, the inner volume 323 of the vapor distributor 320 is typically hotter than the inner volume 331 of the evaporation crucible 330, in order to prevent a condensation of the evaporation material on inner walls of the vapor distributor 320. On the other hand, a major part of the inner volume 331 of the evaporation crucible 330 is to be maintained around the evaporation temperature of the source material 312, for example, slightly below or slightly above the evaporation temperature, in order to allow the source material 312 to evaporate a bit at a time at a predetermined evaporation rate.

The evaporation source 300 may further include a system controller 336 to control various aspects of the evaporation source and vapor deposition apparatus. The system controller 336 facilitates the control and automation of the evaporation source and the vapor deposition apparatus and can include a central processing unit (CPU), memory, and support circuits (or I/O). Software instructions and data can be coded and stored within the memory for instructing the CPU. The system controller 336 can communicate with one or more of the components of the vapor deposition apparatus via, for example, a system bus. A program (or computer instructions) readable by the system controller 336 determines which tasks are performable on a substrate. In some aspects, the program is software readable by the system controller 336, which can include code for monitoring chamber conditions, including independent temperature control of the one or more evaporation sources 300. Although only a single system controller, the system controller 336 is shown, it should be appreciated that multiple system controllers can be used with the aspects described herein.

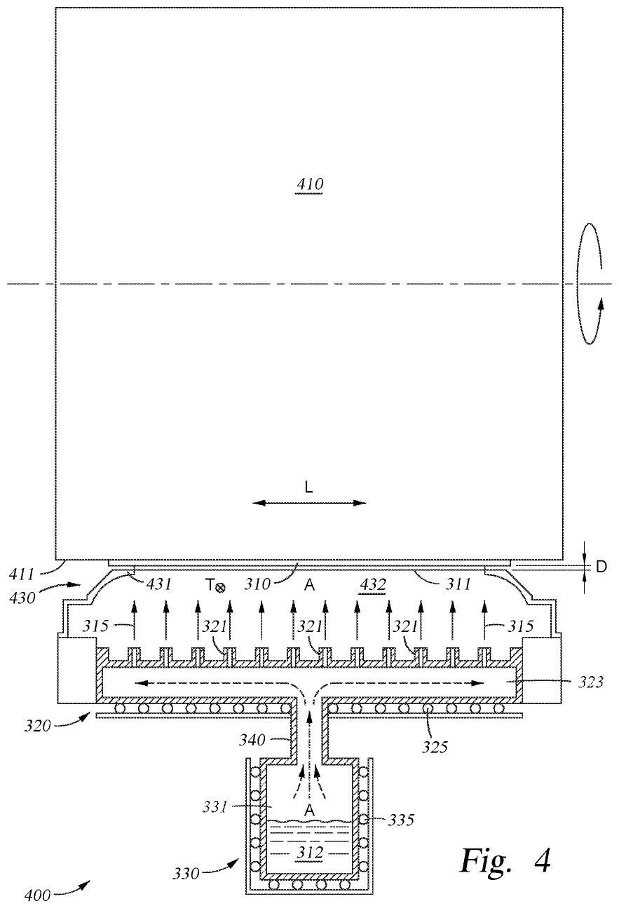

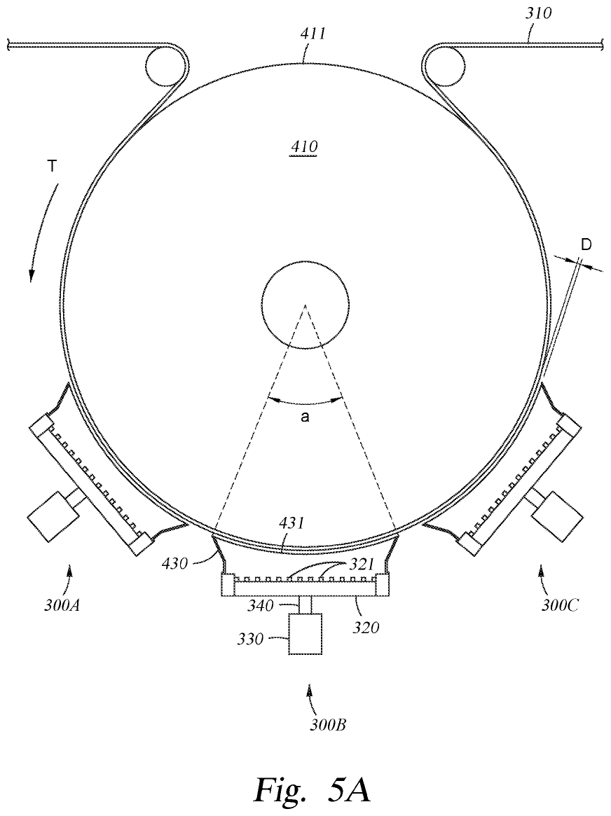

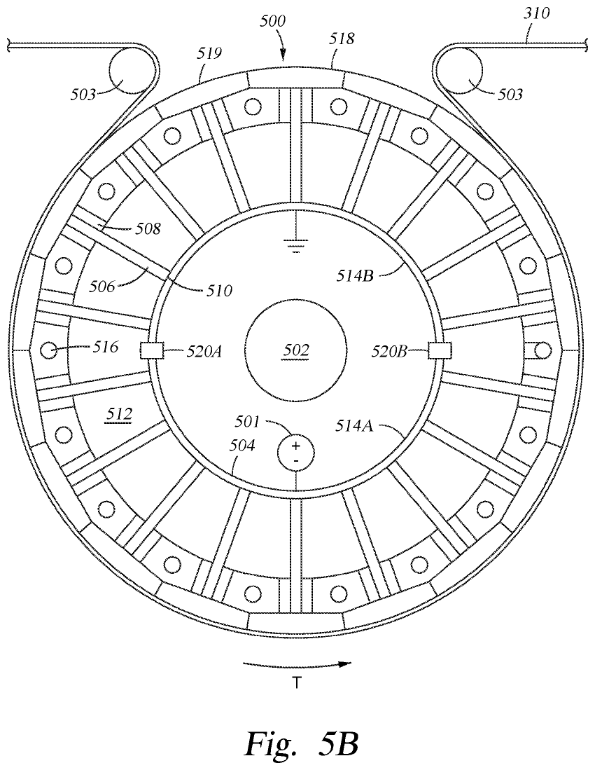

FIG. 4 shows a schematic sectional view of a vapor deposition apparatus 400 according to embodiments of the present disclosure. FIG. 5A shows a schematic view of the vapor deposition apparatus 400 of FIG. 4 viewed along a rotation axis of a rotatable drum 410. The vapor deposition apparatus 400 may include an evaporation source 300 or several evaporation sources according to any of the embodiments described herein, such as evaporation source 300 described relative to FIG. 3.

The vapor deposition apparatus 400 includes a substrate support being a rotatable drum 410 with a curved drum surface 411 for supporting the substrate 310 during deposition. The plurality of nozzles 321 of the evaporation source 300 are directed toward the curved drum surface 411, and the vapor deposition apparatus 400 is configured to move the substrate 310 on the curved drum surface 411 past the evaporation source 300. In some embodiments, several evaporation sources 300 as described herein may be arranged one after the other in the circumferential direction T around the rotatable drum 410, such that the substrate 310 can be subsequently coated by several evaporation sources 300. Different coating materials can be deposited on the substrate 310, or one thicker coating layer of the same coating material can be deposited on the substrate 310 by the evaporation sources 300.

As it is schematically depicted in FIG. 4 and FIG. 5A, the evaporation source 300 includes the evaporation crucible 330 for evaporating a material, the vapor distributor 320 with the plurality of nozzles 321 for directing the evaporated material toward the substrate 310 supported on the rotatable drum 410, and the vapor conduit 340 extending in a conduit length direction “A” from the evaporation crucible 330 to the vapor distributor 320, providing a fluid connection between the evaporation crucible 330 and the vapor distributor 320. At least one nozzle or all nozzles of the plurality of nozzles 321 may have a nozzle axis that extends in, or is essentially parallel to, the conduit length direction “A”. As is depicted in FIG. 4, the conduit length direction “A” may essentially correspond to a radial direction of the rotatable drum 410.

In one or more embodiments, which can be combined with other embodiments described herein, the plurality of nozzles 321 may be arranged in a plurality of nozzle rows extending in a row direction “L” and arranged next to each other in the circumferential direction “T”, wherein the row direction “L” may essentially correspond to an axial direction of the rotatable drum 410. Accordingly, the vapor distributor 320 provides an area showerhead having a plurality of nozzles arranged in a two-dimensional array for reducing the heat load per area on the substrate 310 supported on the curved drum surface 411.

As is depicted in FIG. 5A, three, four or more evaporation sources 300A-300C as described herein may be arranged one after the other in the circumferential direction “T” around the rotatable drum 410. Each evaporation source 300A-300C may define a coating window on the curved drum surface 411 that extends over an angular range (a) of 10° or greater and 45° or less. The conduit length direction “A” of adjacent evaporation sources 300 may enclose an angle of 10° or greater and 45° or less, respectively. Accordingly, the curved drum surface 411 of the rotatable drum 410 is used well for the vapor deposition on a flexible substrate, such as a metal foil or a plastic substrate, and substrate damage can be reduced because the heat load per substrate area can be kept comparatively low while maintaining a high deposition rate.

In one or more embodiments, which can be combined with other embodiments described herein, the evaporation source 300A-300C further includes an edge exclusion shield 430 extending from the evaporation source 300 toward the curved drum surface 411. Referring to FIG. 4, the edge exclusion shield 430 may include an edge exclusion portion 431 for masking areas of the substrate 310 not to be coated, for example, for masking lateral edge areas of the substrate 310 that are to be kept free of coating material. For example, the edge exclusion portion 431 may be configured to mask two opposing lateral edges of the substrate 310.

The edge exclusion portion 431 may extend along the curved drum surface 411 of the rotatable drum 410 in the circumferential direction “T”, following a curvature of the curved drum surface 411. Accordingly, the width “D” of a gap between the curved drum surface 411 and the edge exclusion portion 431 can be kept small (e.g., 2 mm or less) and essentially constant along the circumferential direction T, such that the edge exclusion accuracy can be improved and sharp and well-defined coating layer edges can be deposited on the substrate.

The circumferential direction “T” as used herein may be understood as the direction along the circumference of the rotatable drum 410 that corresponds to the movement direction of the curved drum surface 411 when the rotatable drum 410 rotates around an axis. The circumferential direction “T” corresponds to the substrate transport direction when the substrate 310 is moved past the evaporation source 300 on the curved drum surface 411. In some embodiments, the rotatable drum 410 may have a diameter in a range of about 300 mm to about 1400 mm or larger. Reliably shielding the vapor 315 downstream of the plurality of nozzles 321 for confining the vapor 315 in a vapor propagation volume 432 and providing accurately defined and sharp coating edges is particularly difficult when a flexible substrate is coated that is moved on a curved drum surface 411, because the vapor propagation volume 432 and the coating window may have a complex shape in this case. Embodiments described herein enable a reliable and accurate edge exclusion and material shielding also in vapor deposition apparatuses configured to coat a web substrate provided on a curved drum surface 411. Specifically, the edge exclusion shield 430 may at least partially surround the vapor propagation volume 432 downstream of the plurality of nozzles 321, may confine the vapor 315 in the vapor propagation volume 432, and may provide an accurate edge exclusion through the edge exclusion portions 431.

In one or more embodiments, which can be combined with other embodiments described herein, a heating arrangement for actively or passively heating the edge exclusion shield 430 may be provided. For example, the edge exclusion shield 430 may be heated to a temperature above the condensation temperature of the evaporation material, such that material condensation on the edge exclusion shield 430 can be reduced or prevented. Cleaning efforts can be reduced and the quality of the coating layer edges can be improved. For example, during vapor deposition, the edge exclusion shield 430 may be heated to a temperature of about 500° C. or greater.

The edge exclusion shield 430 does not contact the rotatable drum 410, such that the substrate supported on the rotatable drum 410 can move past the evaporation source 300 and past the edge exclusion shield 430 during vapor deposition.

The vapor deposition apparatus 400 may be a roll-to-roll deposition system for coating a flexible substrate, for example, a foil or a plastic substrate. The substrate 310 to be coated may have a thickness of 50 μm or less, particularly 20 μm or less, or even 6 μm or less. For example, a metal foil, a flexible metal-coated foil, a polymer substrate, or a flexible polymer substrate may be coated in the vapor deposition apparatus 400. In some embodiments, the substrate 310 is a thin copper foil or a thin aluminum foil having a thickness below 30 μm, for example, 6 μm or less. The substrate 310 could also be a thin metal foil (e.g., a copper foil) or a polymer substrate (e.g., a PET substrate) coated with graphite, silicon, silicon oxide, or any combination thereof, for example, in a thickness of 150 μm or less, particularly 100 μm or less, or even down to 50 μm or less. According to some embodiments, the web may further contain graphite, silicon, silicon oxide, or any combination thereof. For example, the lithium may pre-lithiate the layer including graphite, silicon, silicon oxide, or any combination thereof.

In a roll-to-roll deposition system, the substrate 310 may be unwound from a storage spool, at least one or more material layers may be deposited on the substrate 310 while the substrate 310 is guided on the curved drum surface 411 of the rotatable drum 410, and the coated substrate may be wound on a wind-up spool after the deposition and/or may be coated in further deposition apparatuses.

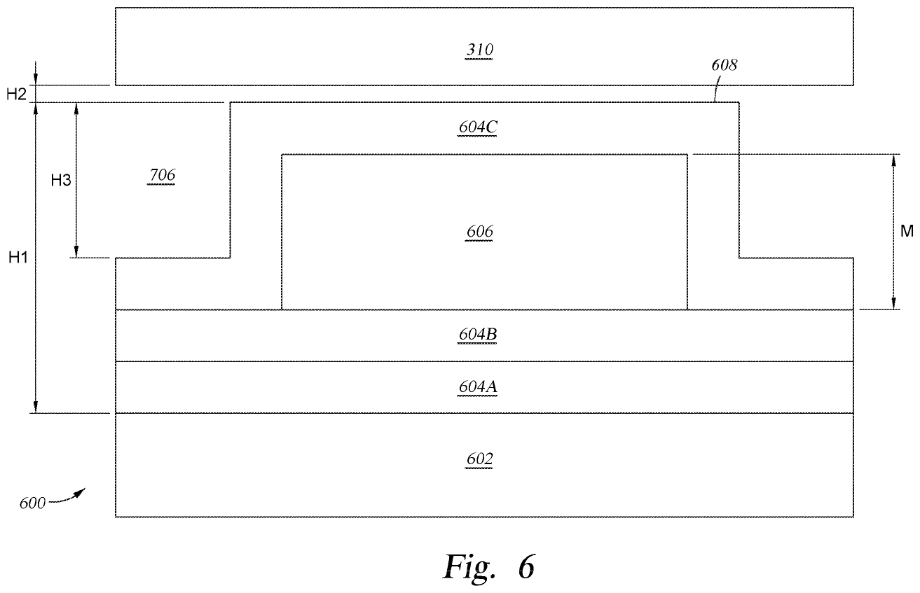

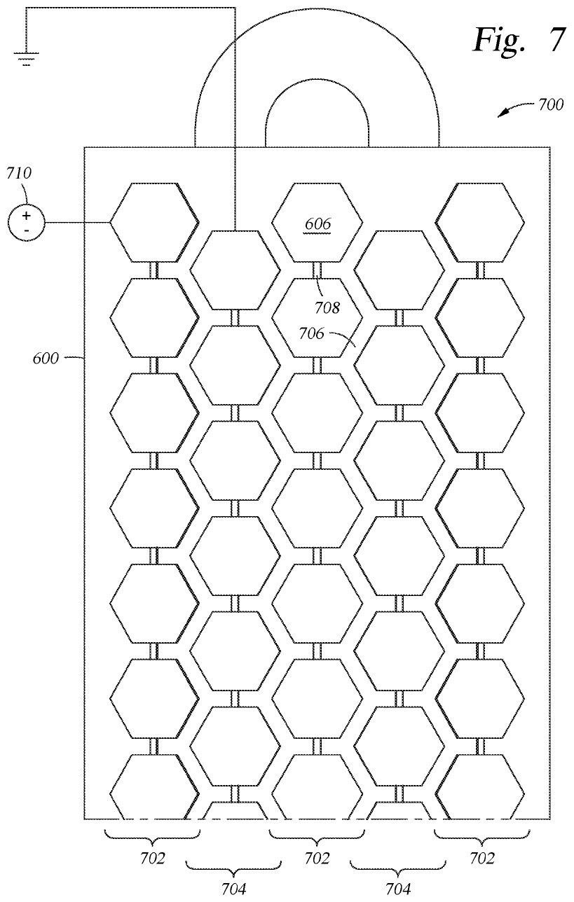

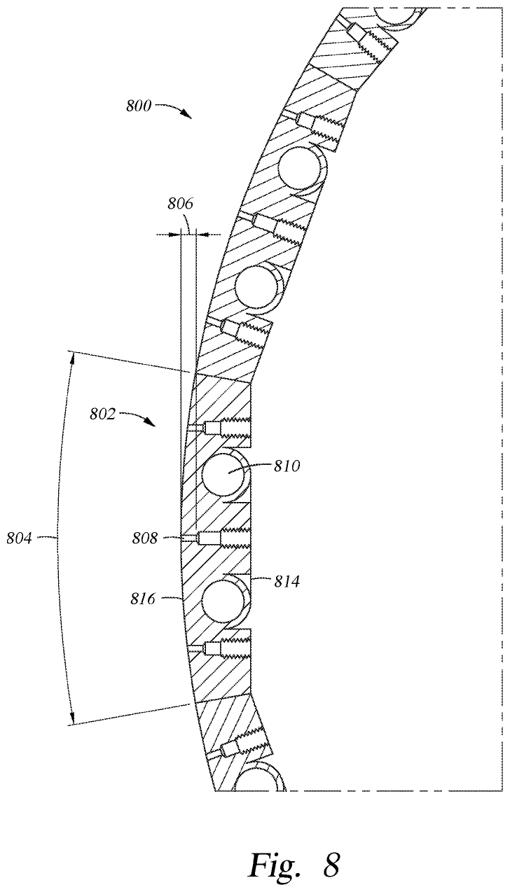

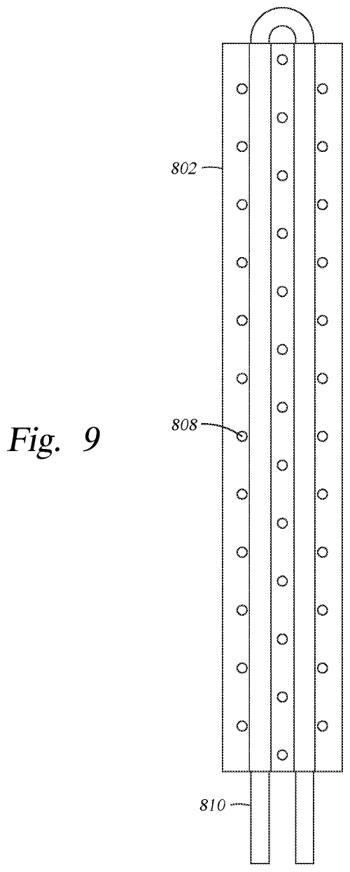

The substrate 310 is retained on the curved drum surface 411 using an electrostatic chuck incorporated within the rotatable drum 410. Depending on the substrate type or material, the electrostatic chuck can be integrated in the rotatable drum 410 in various embodiments, such as the configurations shown in FIG. 5B, or FIG. 6 and FIG. 7, or FIG. 8 and FIG. 9.

FIG. 5B depicts cross-sectional end view of a rotatable drum 500 conveying a substrate 310. The rotatable drum 500 guides the substrate 310 with the assistance of a plurality of rollers 503. The rotatable drum 500 includes a drum shaft 502 at a center of the rotatable drum 500. An electrode 504 at least partially surrounds the drum shaft 502. In some embodiments, the electrode 504 is a powered electrode that completely surrounds the drum shaft 502, which is referred to herein as having a monopolar configuration. In some embodiments, the electrode 504 includes a first hemisphere 514A and a second hemisphere 514B. In some embodiments, a power of about −1300V to about −1200V DC power is supplied to the electrode 504 from a power source 501. The first hemisphere 514A is powered and the second hemisphere 514B is grounded, which is referred to herein as having a bipolar configuration. The first hemisphere 514A and the second hemisphere 514B can be electrically isolated using a dielectric isolator 520A-B. In some embodiments, the electrode 504 is fixed and is electrically coupled to a curved surface 518 of the rotatable drum 500.

The electrode 504 is electrically coupled to the curved surface 518 by a plurality of movable electrode spokes 506 extending from the electrode 504 to the curved surface 518. In some embodiments, the spokes 506 extend through a body 512 of the rotatable drum 500. The spokes 506 are electrically isolated from the body 512 of the rotatable drum 500 by a dielectric isolator 508. The spokes 506 are electrically coupled to the electrode 504 at a connection 510 that can be made or broken depending on the desired chucking or de-chucking. The body 512 of the rotatable drum 500 is a metal, such as stainless steel, or a copper containing material. The body 512 of the rotatable drum 500 is water cooled and includes a plurality of gas channels 516. The plurality of gas channels 516 form a heat sink for maintaining a substrate temperature of about 200° C. or less, such as about 60° C. to about 180° C., such as about 100° C. to about 160° C., such as about 120° C. to about 140° C. In some embodiments, the substrate is copper and has a thickness of about 4 μm to about 6 μm. Without being bound by theory, it is believed that thin substrates are more prone to thermal expansion which can lead to substrate defects. For substrates for use in battery anodes, a polymer binder is often used which can melt, degrade or lose binding properties when exposed to hot temperatures, such as hot lithium. It has been discovered that efficiently maintaining a substrate temperature using the apparatus and methods provided herein enables increased throughput without affecting the substrate properties.

The body 512 is surrounded by a dielectric portion 519, such as a dielectric coating, such as a spray coating. The dielectric portion 519 can be implemented in various ways depending on attributes of the substrate to be retained on the rotatable drum 500. In some embodiments, the dielectric portion 519 includes an electrode structure patterned thereon. In some embodiments, the dielectric portion 519 includes diamond-like carbon, aluminum oxide, boron nitride, polyimide, or combinations thereof.

FIG. 6 depicts a cross sectional view of a portion of a dielectric portion 600, which can be used as the dielectric portion 519 of FIG. 5B. The dielectric portion 600 includes a base layer 602, such as a copper containing layer, a first protective layer 604A disposed over the base layer 602, a second protective layer 604B disposed over the first protective layer 604A, and a patterned electrode 700 (e.g., depicted in FIG. 7) including a plurality of mesa structures 606 formed over the second protective layer 604B. A third protective layer 604C is formed over the plurality of mesa structures 606 and the substrate 310 can be retained over the third protective layer 604C. Each of the protective layers 604A, 604B, 604C can independently be adhesive layers, such as one or more polyimide layers. In one or more examples, the first protective layer 604A can be or include a first polyimide layer, the second protective layer 604B can be or include a second polyimide layer, and the third protective layer 604C can be or include a third polyimide layer. In some embodiments, the protective layers 604A-C can be or contain aluminum oxide and the patterned electrode 700, for example, the mesa structures 606 can be or include an aluminum-containing material, such as aluminum or an alloy of aluminum. In some embodiments, the patterned electrode 700 covers an entire surface of the drum surface.

In some embodiments, the mesa structures 606 include a mesa height “M” of about 100 μm to about 300 μm, such as about 120 μm to about 200 μm. In some embodiments a stack height “H1” of the first protective layer 604A, the second protective layer 604B, and the third protective layer 604C together with the mesa structure 606 can be about 100 μm to about 400 μm, such as about 200 μm to about 250 μm. Referring to FIG. 7, in some embodiments, channels 706 are formed between adjacent mesa structures 606. Referring to FIG. 6, in some embodiments, the channels 706 formed between adjacent mesa structures 606 have a height “H3” of about 100 μm to about 300 μm. In some embodiments a gap height “H2” between the substrate 310 and a surface 608 of the protective layer 604C is about 0.5 μm to 10 μm, such as about 1 μm to about 8 μm, such as about 2 μm to about 6 μm.

FIG. 7 depicts a top view of the dielectric portion 600. The plurality of mesa structures 606 can be arranged in rows 702, 704. Each of the mesa structures 606 of each row can be connected in series (e.g., connections 708) and connected to a power source 710 or to a ground. In some embodiments, each row 702 that is powered is alternated with a row 704 that is grounded. Alternating between powered and grounded electrode rows is referred to herein as having a bipolar configuration and enables retaining substrates made from a variety of different materials such as paper and plastic, for example, PET. Alternatively, all of the rows 702, 704 are powered and the substrate is a grounded foil, which is referred to herein as having a monopolar configuration. Each row of mesa structures 606 is spaced apart by channels 706 which enable gas to flow between the mesa structures 606. The gas can be flowed substantially parallel to the surface 608 of the dielectric portion 600 to enable a gap, for example, the gap defined by “H2”, between the surface 608 and a backside of the substrate 310. In some embodiments, instead of the mesa structures 606, the electrodes are strips of elongated, continuous structures extended from one edge of the dielectric portion 600 to an opposing edge. Each of the electrode strips can be powered in a monopolar configuration, or alternated between powered and grounded in a bipolar configuration. In some embodiments, argon is supplied through gas nozzles parallel to surface of the drum to maintain the gap. The nozzle includes a diameter of about 200 μm to about 1000 μm, such as about 300 μm to about 500 μm.

FIG. 8 illustrates a cross sectional end view of a dielectric portion 600 coupled to a body of the drum, according to some embodiments described herein. The dielectric portion 600 can be coupled to a body 800 of the drum as depicted in a cross sectional end view shown in FIG. 8. The body 800 of the rotatable drum can include a plurality of segments 802, such as one or more circumferential segments. The plurality of segments 802 can include gas channels 810, such as cooling channels for cooling. In some embodiments, the drum is about 200 mm to about 700 mm in diameter, such as about 300 mm to about 600 mm, such as about 400 mm to about 500 mm in diameter. In some embodiments, the body 800 can include about 10 to about 40 segments, such as about 22 to about 32. An arc angle 804 of a segment of the plurality of segments 802 can be about 10 degrees to about 40 degrees depending on the number of segments, such as about 15 degrees to about 20 degrees. In some embodiments, the body 800 can include gas nozzles 808 extending from an inner surface 814 of the body 800 to an outer surface 816 of the body 800. FIG. 9 depicts an inside view of the gas channels 810 and the gas nozzles 808 of the segment 802.

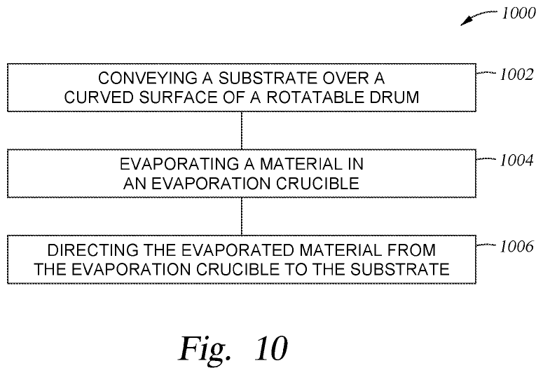

FIG. 10 is a flow diagram illustrating a method 1000 for coating a substrate according to embodiments described herein.

In operation 1002, a substrate, for example, the substrate 310, is conveyed over a curved surface of a rotatable drum, for example, the curved surface 518 of the rotatable drum 500. In some embodiments, the substrate is retained on the curved surface using low tension pressure, such as about 20 N/m or less, such as about 5 N/m to about 15 N/m, such as about 10 N/m to about 12 N/m. The tension pressure enables a uniform gap between the substrate and the curved surface prior to clamping the substrate. The gap has a variation of about 75 μm or less. The rotatable drum includes one or more electrodes such that the substrate is electrostatically chucked to at least a portion of the curved surface of the rotatable drum. After applying the electrostatic clamping a gap variation is reduced to about 10 μm or less.

In operation 1004, a material is evaporated in an evaporation crucible. For example, a metal such as lithium is evaporated in the evaporation crucible, for example, the evaporation crucible 330. The evaporation crucible may be heated to a first temperature of about 500° C. or greater, such as about 600° C. to about 1200° C., such as about 700° C. to about 1000° C.

In operation 1006, the evaporated material is directed from the evaporation crucible to the substrate. As the evaporated material is directed to the substrate, the substrate is retained over the curved surface of the rotatable drum such that a gap is formed between the substrate and the curved surface of the rotatable drum. A gas, such as a non-reactive gas, such as argon, is provided to the gap between a backside of the substrate and the curved surface of the rotatable drum. In some embodiments, the gap is about 0.5 μm to 10 μm, such as about 1 μm to about 8 μm, such as about 2 μm to about 6 μm. As the evaporated material is being deposited onto the substrate, the substrate is continuously conveyed in machine direction extending from an inlet side to an outlet side of the rotatable drum. The substrate is chucked at the inlet side and dechucked at the outlet side to release the substrate from the drum surface.

In some embodiments, the substrate is a flexible substrate that is supported on the curved drum surface of a rotatable drum during the deposition. Specifically, the substrate may be moved past a plurality of nozzles depositing the material on the substrate on the curved drum surface of the rotatable drum.

The substrate may be a flexible foil, particularly a flexible metal foil, more particularly a copper foil or a copper-carrying foil, for example, a foil that is coated with copper on one or both sides thereof. The substrate may have a thickness of 50 μm or less, particularly 20 μm or less, for example, about 8 μm. In some embodiments, the substrate may be a thin copper foil having a thickness in a sub 20-μm range.

According to some embodiments, which can be combined with other embodiments described herein, an anode of a battery is manufactured, and the flexible substrate includes a polymer, copper or a copper alloy or consists of copper or a copper alloy. According to some embodiments, the web may further contain graphite, silicon, silicon oxide, or any combination thereof. For example, the lithium may pre-lithiate the layer including graphite, silicon, and/or silicon oxide.

The deposition of a metal, e.g., lithium, on a flexible substrate, for example, on a copper substrate, by evaporation may be used for the manufacture of batteries, such as Li-batteries. For example, a lithium layer may be deposited on a thin flexible substrate for producing the anode of a battery. After assembly of the anode layer stack and the cathode layer stack, optionally with an electrolyte and/or separator therebetween, the manufactured layer arrangement may be rolled or otherwise stacked to produce the Li-battery.

The previously described embodiments of the present disclosure have many advantages, including enabling improved vapor deposition on flexible substrates. The rotatable drum can rotate during deposition to expose different areas of the substrate to the deposition environment while maintaining a uniform gap height across the web, which improves heat transfer across the substrate. Electrostatic clamping resists “ballooning” or “web slip” at high gap pressure and can maximize heat transfer coefficient to enable web coating at low thermal budget, for example, less than 80 degrees Celsius, to increase throughput. However, the present disclosure does not require that all the advantageous features and all the advantages need to be incorporated into every embodiment of the present disclosure.

In the Summary and in the Detailed Description, and the Claims, and in the accompanying drawings, reference is made to particular features (including method operations) of the present disclosure. It is to be understood that the disclosure in this specification includes all possible combinations of such particular features. For example, where a particular feature is disclosed in the context of a particular aspect, embodiment, embodiment, or example of the present disclosure, or a particular claim, that feature can also be used, to the extent possible in combination with and/or in the context of other particular aspects and embodiments of the present disclosure, and in the present disclosure generally.

Embodiments and all of the functional operations described in this specification can be implemented in digital electronic circuitry, or in computer software, firmware, or hardware, including the structural means disclosed in this specification and structural equivalents thereof, or in combinations of them. Embodiments described herein can be implemented as one or more non-transitory computer program products, i.e., one or more computer programs tangibly embodied in a machine readable storage device, for execution by, or to control the operation of, data processing apparatus, e.g., a programmable processor, a computer, or multiple processors or computers.

The processes and logic flows described in this specification can be performed by one or more programmable processors executing one or more computer programs to perform functions by operating on input data and generating output. The processes and logic flows can also be performed by, and apparatus can also be implemented as, special purpose logic circuitry, e.g., an FPGA (field programmable gate array) or an ASIC (application specific integrated circuit).

The term “data processing apparatus” encompasses all apparatus, devices, and machines for processing data, including by way of example a programmable processor, a computer, or multiple processors or computers. The apparatus can include, in addition to hardware, code that creates an execution environment for the computer program in question, e.g., code that constitutes processor firmware, a protocol stack, a database management system, an operating system, or a combination of one or more of them. Processors suitable for the execution of a computer program include, by way of example, both general and special purpose microprocessors, and any one or more processors of any kind of digital computer.

Computer readable media suitable for storing computer program instructions and data include all forms of nonvolatile memory, media and memory devices, including by way of example semiconductor memory devices, e.g., EPROM, EEPROM, and flash memory devices; magnetic disks, e.g., internal hard disks or removable disks; magneto optical disks; and CD ROM and DVD-ROM disks. The processor and the memory can be supplemented by, or incorporated in, special purpose logic circuitry.

The term “comprises” and grammatical equivalents thereof are used herein to mean that other components, ingredients, operations, etc. are optionally present. For example, an article “comprising” (or “which comprises”) components A, B, and C can consist of (i.e., contain only) components A, B, and C, or can contain not only components A, B, and C but also one or more other components. In addition, whenever a composition, an element or a group of elements is preceded with the transitional phrase “comprising” or grammatical equivalents thereof, it is understood that it is contemplated that the same composition or group of elements may be preceded with transitional phrases “consisting essentially of,” “consisting of,” “selected from the group of consisting of,” or “is” preceding the recitation of the composition, element, or elements and vice versa.

Where reference is made herein to a method comprising two or more defined operations, the defined operations can be carried out in any order or simultaneously (except where the context excludes that possibility), and the method can include one or more other operations which are carried out before any of the defined operations, between two of the defined operations, or after all of the defined operations (except where the context excludes that possibility).

While the foregoing is directed to embodiments, other and further embodiments may be devised without departing from the basic scope, and the scope is determined by the claims that follow.

What is claimed is:

1. A rotatable drum for supporting a substrate, comprising:
a curved drum surface for supporting the substrate and comprising a dielectric portion; and
an electrode coupled to a power source, the electrode electrically coupled to the curved drum surface and capable of chucking and de-chucking the substrate from the curved drum surface at one or more circumferential segments of the curved drum surface.

2. The rotatable drum of claim 1, wherein the dielectric portion comprises a material selected from the group consisting of diamond-like carbon, aluminum oxide, boron nitride, polyimide, and combinations thereof.

3. The rotatable drum of claim 1, wherein the electrode is a fixed electrode spaced radially inward from the curved drum surface and is electrically coupled to the curved drum surface by a plurality of movable electrode spokes.

4. The rotatable drum of claim 1, wherein the electrode comprises a first hemisphere that is electrically grounded and a second hemisphere that is coupled to the power source.

5. The rotatable drum of claim 1, wherein each of the one or more circumferential segments includes at least one cooling channel and one or more gas passages extending from an inner surface of the circumferential segment to the curved drum surface.

6. The rotatable drum of claim 1, wherein the dielectric portion of the curved drum surface comprises:
a first polyimide layer;
a patterned electrode disposed over the first polyimide layer; and
a second polyimide layer disposed over the patterned electrode.

7. The rotatable drum of claim 6, wherein the patterned electrode comprises copper.

8. The rotatable drum of claim 6, wherein the patterned electrode comprises a plurality of mesas.

9. The rotatable drum of claim 8, wherein the mesas are polygon shaped.

10. The rotatable drum of claim 8, wherein the mesas are arranged in rows extended from one edge of the rotatable drum to an opposite edge of the rotatable drum.

11. The rotatable drum of claim 8, further comprising surface channels disposed between adjacent rows of the patterned electrode, wherein the rows alternate between a first row that is coupled to a power source and a second row that is coupled to a ground.

12. The rotatable drum of claim 1, further comprising a heat sink disposed radially inward from the curved drum surface and radially outward from the electrode.

13. A vapor deposition apparatus, comprising:
the rotatable drum of claim 1; and
an evaporation source configured to deposit a material onto a substrate disposed on the curved drum surface of the rotatable drum.

14. An electrode assembly for electrostatically chucking a substrate to a rotatable drum, comprising:
a first protective layer interfacing the rotatable drum;
an electrode disposed over the first protective layer; and
a second protective layer disposed over the electrode and comprising a curved surface for supporting the substrate.

15. The electrode assembly of claim 14, wherein the first and second protective layers comprise aluminum oxide and the electrode comprises aluminum or an alloy of aluminum.

16. The electrode assembly of claim 14, wherein the electrode is arranged in a plurality of rows extending substantially parallel with respect to one another and extending from one edge of the rotatable drum to an opposite edge of the rotatable drum.

17. The rotatable drum of claim 16, wherein the rows alternate between a first row that is coupled to power and a second row that is grounded and channels are disposed between the rows.

18. A method for coating a substrate in a vacuum chamber, comprising:
conveying a substrate over a curved surface of a rotatable drum, the substrate being electrostatically chucked to at least a portion of the curved surface of the rotatable drum;
evaporating a material in an evaporation crucible; and
directing the evaporated material from the evaporation crucible to the substrate.

19. The method of claim 18, wherein conveying the substrate further comprises retaining the substrate over the curved surface of the rotatable drum such that a gap is formed between the substrate and the curved surface of the rotatable drum.

20. The method of claim 19, further comprising providing a gas to the gap between a backside of the substrate and the curved surface of the rotatable drum.
